(19) United States
(12) Patent Application Publication
(10) Pub. No.: US 2026/0144141 A1
(43) Pub. Date: May 21, 2026

(54) PACKAGE STRUCTURE AND METHOD OF FORMING THE SAME

(71) Applicant: Taiwan Semiconductor Manufacturing Company, Ltd., Hsinchu (TW)

(72) Inventors: Tzuan-Horng Liu, Taoyuan City (TW); An-Jhih Su, Taoyuan City (TW); Chung-Ming Weng, Taichung City (TW)

(73) Assignee: Taiwan Semiconductor Manufacturing Company, Ltd., Hsinchu (TW)

(21) Appl. No.: 18/951,644

(22) Filed: Nov. 19, 2024

(51) Int. Cl. H01L 25/10; H01L 23/00; H01L 23/31; H01L 23/498; H01L 25/00

(52) U.S. Cl. CPC H10W 90/00; H10W 74/121; H10W 90/701; H10W 70/60; H10W 70/6528; H10W 90/10; H10W 90/20

(57) ABSTRACT

A package structure and a method of forming the same are provided. The package structure includes a redistribution structure disposed on a first die, and a second die disposed on the redistribution structure and electrically connected to the first die. The package structure includes a through insulator via (TIV) wall encircling the second die. The package structure includes TIVs disposed on the redistribution structure, and surrounding the TIV wall and the second die. The package structure includes an underfill disposed between the second die and the TIV wall, and between the second die and the redistribution structure. The package structure includes an encapsulant disposed on the redistribution structure, and laterally wrapping around the second die, the TIV wall and each of the TIVs. The TIV wall is electrically floating and the TIVs are electrically connected to the first die.

### BACKGROUND

The quality of a package structure has great impact on the performance of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 3 are schematic cross-sectional views of stages in a formation method of a semiconductor die in accordance with some embodiments of the present disclosure.

FIG. 4 to FIG. 15 are schematic top views and cross-sectional views illustrating various stages of the formation method of a package structure in accordance with some embodiments of the present disclosure.

FIG. 16A to FIG. 20 are schematic top views and cross-sectional views illustrating various stages of the formation method of a package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package structure and a method of forming the package structure are provided. The package structure includes a die, a TIV wall around the die, an array of TSVs around the TIV wall. A top surface of the TIV wall substantially aligns with top surfaces of the TIVs. When an underfill is applied to a gap between the die and the TIV wall, the TIV wall blocks the spread of the underfill. Thus, the TIV wall prevents the underfill spreading to the TSVs, so as to reduce the impact of the underfill spread on TSV signaling. Besides, the keep out zone (KOZ) between the die and the TSVs is also reduced since the span of the underfill is limited by the TIV wall. As a result, the TIV depopulation is mitigated, the Power Delivery Network (PDN) performance is improved, the limitation of the I/O design, the P/G design and the routability of the TIVs is decreased, and the cost is lowered. In accordance with some embodiments of the present disclosure, embodiments discussed herein are to provide examples to enable making or using the subject matter of this disclosure, and a person having ordinary skill in the art will readily understand modifications that can be made while remaining within contemplated scopes of different embodiments.

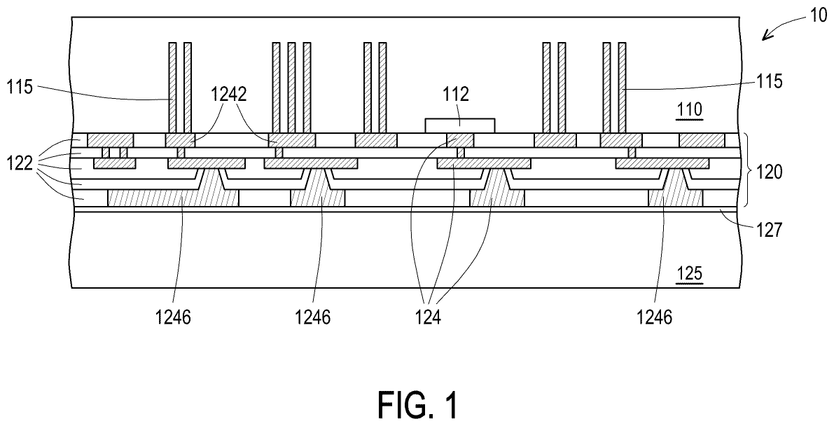

FIG. 1 to FIG. 3 are schematic cross-sectional views of stages in a formation method of a semiconductor die in accordance with some embodiments of the present disclosure.

Referring to FIG. 1, an exemplary semiconductor structure 10 according to an embodiment of the present disclosure is illustrated. The exemplary semiconductor structure 10 includes a substrate 110 and metallic vias 115 extending into the substrate 110. The substrate 110 may be a semiconductor wafer, such as a silicon wafer, in some embodiments. Other substrates, such as a silicon-on-insulator (SOI) substrate, a multi-layered substrate, or a gradient substrate may also be used. The substrate 110 may be doped (e.g., with a p-type or an n-type dopant) or undoped. In some embodiments, the semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In some embodiments, a device layer 112 is formed with active devices (e.g., transistors, diodes, or the like), passive devices (e.g. capacitors, resistors, inductors, or the like) and/or integrated circuits (ICs) in the substrate 110.

In some embodiments, the formation of the metallic vias 115 involves, for example, forming openings extending into the substrate 110 using acceptable photolithography and etching techniques, such as dry etching or wet etching, later a metallic material is formed inside the openings to fill up the openings, thereby forming the metallic vias 115. In some embodiments, a liner (not shown) may be deposited in the openings prior to forming the conductive metallic material. The conductive metallic material is or includes, for example, a metal or a metal alloy, including copper, silver, gold, tungsten, cobalt, aluminum, alloys thereof, or combinations thereof.

In some embodiments, a redistribution structure 120 is formed on the substrate 110 and on the metallic vias 115, and the redistribution structure 120 is electrically connected with the metallic vias 115. In some embodiments, as seen in FIG. 1, the redistribution structure 120 includes multiple layers of conductive features 124 sandwiched between multiple dielectric layers 122 (not individually illustrated). The conductive features 124 may include metallization patterns such as routing lines, conductive vias, contact pads, and the layers of the conductive features function as redistribution layers for electrical interconnections and electrical routing. In some embodiments, the conductive features 124 includes pads 1242 that are located on the surface of the substrate 110 and are connected with the metallic vias 115 and contact pads 1246 exposed from the bottommost dielectric layer 122. In some embodiments, the redistribution structure 120 may have multiple layers of conductive features 124 and multiple dielectric layers 122, but the numbers of layers of the conductive features 124 or dielectric layers 122 may be varied depending on the design of the products. The conductive features 124 may be formed of a metal material using any suitable techniques such as deposition, damascene, dual damascene, or the like. The metal material of the conductive features 124 may include, for example, copper, silver, gold, tungsten, cobalt, ruthenium, aluminum, alloys thereof, or combinations thereof. The dielectric layers 122 may be formed using acceptable polymeric materials such as polybenzoxazole (PBO), polyimide, benzocyclobuten (BCB) based polymers, or the like.

Referring to FIG. 1, following the formation of the redistribution structure 120, the whole structure of the semiconductor structure 10 including the substrate 110 having the metallic vias 115 and the redistribution structure 120 formed on the substrate 110 is placed on a support structure 125. In some embodiments, the semiconductor structure 10 is attached to the support structure 125 through an adhesive layer 127 in direct contact with the redistribution structure 120.

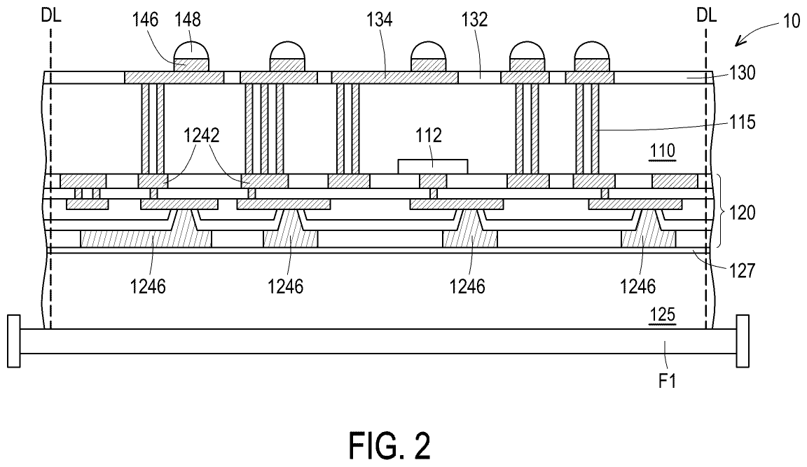

Referring to FIG. 2, the semiconductor structure 10 is placed on a film carrier F1. In some embodiments, a thinning process is performed to the backside of the semiconductor structure 10 to partially remove the substrate 110 until the ends of the metallic vias 115 are exposed and the metallic vias 115 become through semiconductor vias (TSVs). The thinning process includes performing an etching process, a grinding process or a chemical mechanical polishing (CMP) process, for example. Later, a backside redistribution structure 130 is formed on the substrate 110 and electrically connected to the TSVs 115. In some embodiments, the backside redistribution structure 130 includes one or more layers of conductive features 134 embedded in at least one dielectric layer 132. For example, the dielectric layer 132 and the conductive features 134 may be formed using the same materials and the same processes used for forming the dielectric layers 122 and the conductive features 124 as described previously. In some embodiments, some of the conductive features 134 may be directly formed on the substrate 110 and electrically connected to the TSVs 115 without being covered by the dielectric layer 132.

Referring to FIG. 2, micro-connectors 146 are formed on the conductive features 134 of the backside redistribution structure 130 and electrically connected to the device layer 112 through the redistribution structure 120, the TSVs and the conductive features 134 of the backside redistribution structure 130. The micro-connectors 146 may be or include micro-bumps, copper posts, or metal posts with solder pastes. In some embodiments, the micro-connectors 146 include solder material portions 148.

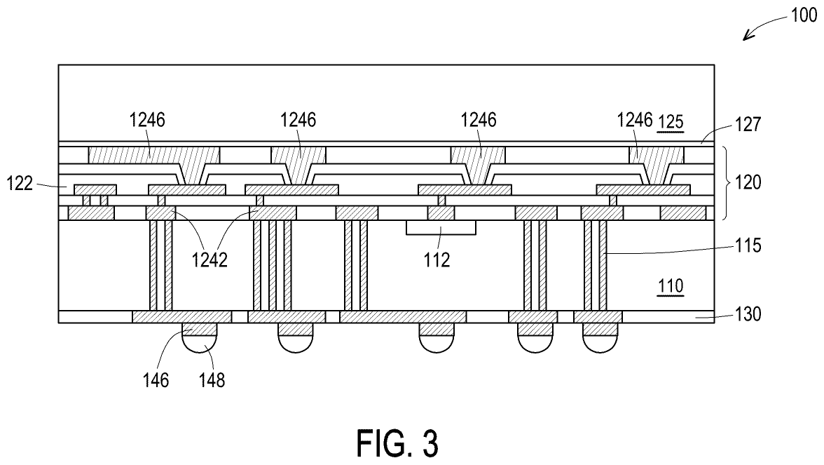

Referring to FIG. 2 and FIG. 3, after the formation of the micro-connectors 146 with solder material portions 148, a singulation process is performed to the semiconductor structure 10 (in wafer form), cutting through the redistribution structures 130, 120, the substrate 110, and the support structure 125. In some embodiments, the singulation process includes performing a wafer dicing process cutting along dicing lines DL to form TSV dies 100. Only one TSV die 100 is shown upside down with the support structure 125 at the top and the micro-connectors at the bottom as shown in FIG. 3.

Referring to FIG. 3, as the exemplary structure, the TSV die 100 includes the substrate 110, TSVs 115 penetrating through the substrate 110, the redistribution structures 120 and 130 disposed at two opposite sides of the substrate 110, and the micro-connectors 146 with solder material portions 148 disposed on the redistribution structure 130.

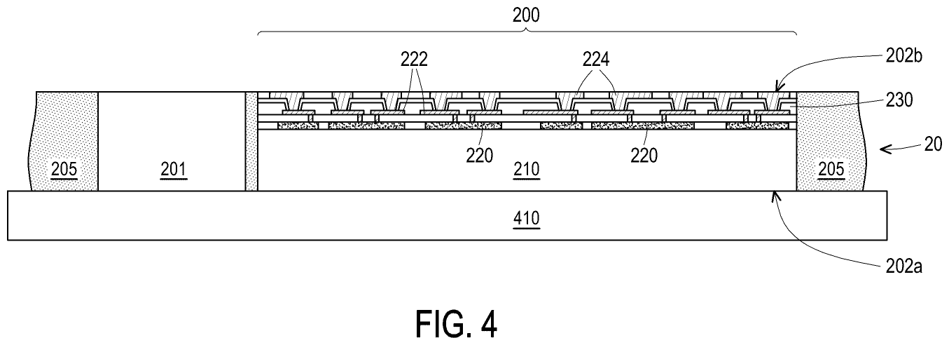

FIG. 4 to FIG. 15 are schematic top views and cross-sectional views illustrating various stages of the formation method of a package structure in accordance with some embodiments of the present disclosure

Referring to FIG. 4, an exemplary structure of a reconstructed wafer structure 20 according to an embodiment of the present disclosure is illustrated. In some embodiments, the reconstructed wafer structure 20 includes semiconductor dies 200 and dummy dies 201 disposed side-by-side and laterally wrapped by a first encapsulant 205, and only a portion of the reconstructed wafer structure 20 is shown with only one semiconductor die 200 and one dummy die 201. For example, the reconstructed wafer structure 20 is placed on and temporarily attached to a top side of a first temporary carrier 410. The first temporary carrier 410 may be a glass carrier. The reconstructed wafer structure 20 may include an array of units, and a single unit may include a set of at least one semiconductor die 200 and optionally at least one dummy die 201 within each unit.

For example, the semiconductor die 200 may include a system-on-chip (SoC) die, a logic die, a memory die, or a semiconductor die of any other types. In one embodiment, a semiconductor die 200 may include a semiconductor substrate 210, device layers 220 formed on the semiconductor substrate 210 and formed within a dielectric material layer 230, interconnect structures 222 formed within the dielectric material layers 230 and connected to the device layers 220, and contacts 224 formed within the dielectric material layer 230 and connected to the interconnect structures 222. For example, the semiconductor substrate may include a single crystalline semiconductor substrate such as a bulk silicon substrate. In some embodiments, the device layers 220 include semiconductor devices including active devices (such as transistors, diodes or any other type of semiconductor devices known in the art) and optionally passive devices (such as resistors, capacitors, inductors) formed in the semiconductor substrate 210. The semiconductor devices in the device layers 220 are electrically connected with the contacts 224 through the interconnect structures 222.

In some embodiments, the semiconductor die 200 faces up with its contacts 224 exposed and its backside facing the first temporary carrier 410. The semiconductor die 200 is spaced apart from the dummy die 201 with the first encapsulant 205 located there-between. In the reconstructed wafer structure 20, the semiconductor die 200 includes a backside surface 202a attached to the first temporary carrier 410 and an active surface 202b opposite to the backside surface 202a. In FIG. 4, the active surface 202b of the semiconductor die 200 levels with top surfaces of the first encapsulant 205 and the dummy die(s) 201.

In some embodiments, the first encapsulant 205 may be formed of an insulating resin material such as epoxy resins, phenolic resins or a molding compound material. The material of the first encapsulant 205 may include an epoxy resin material that may be hardened (i.e., cured) to provide a dielectric material portion having sufficient stiffness and mechanical strength. The material of the first encapsulant 205 may include hardener, silica (as a filler material), and other additives. The material of the first encapsulant 205 may be provided in a liquid form or in a solid form depending on the viscosity and flowability suitable for processing.

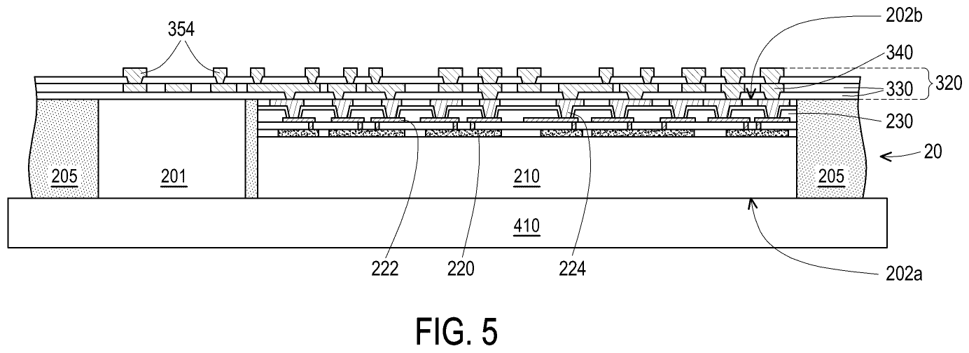

Referring to FIG. 5, a first redistribution structure 320 is formed on the active surface 202b of the semiconductor dies 200. The first redistribution structure 320 includes first redistribution patterns 340 formed within the first redistribution dielectric layers 330, and first pedestal patterns 354 formed on a topmost first redistribution dielectric layer 330.

The first redistribution patterns 340 formed within first redistribution dielectric layers 330 may be formed over the reconstituted wafer including the semiconductor dies 200 and the dummy dies 201. The first redistribution dielectric layers 330 include a respective dielectric polymer material such as polyimide (PI), benzocyclobutene (BCB), or polybenzobisoxazole (PBO). Other suitable dielectric polymer material may also be used. Each first redistribution dielectric layer 330 may be formed by spin coating and drying of the respective dielectric polymer material. For example, the thickness of each first redistribution dielectric layer 330 may be in a range from about 2 μm to 20 μm. Each first redistribution dielectric layer 330 may be patterned through, for example, photolithographic and etching processes by applying a respective photoresist layer there-above.

The formation of the first redistribution patterns 340 may involve depositing a metallic seed layer by sputtering, applying a photoresist pattern over the metallic seed layer, electroplating a metallic material, and etching extra portions of the metallic seed layer and the metallic material. In some embodiments, the metallic seed layer includes a stack of a titanium barrier layer and a copper seed layer. For example, the titanium barrier layer has a thickness in a range from 50 nm to 300 nm, and the copper seed layer has a thickness in a range from 100 nm to 500 nm. In some embodiments, the metallic material for the first redistribution patterns 340 may include aluminum, copper, titanium, nickel, or alloys thereof. For example, the thickness of the metallic material that is deposited for each first redistribution patterns 340 may be in a range from about 2 μm to 10 μm, although lesser or greater thicknesses may also be used. The total number of levels of the first redistribution patterns 340 is not limited.

The first pedestal patterns 354 may be formed by deposition and patterning of a metallic bonding material. In one embodiment, the first pedestal patterns 354 include copper stud structures that are formed by deposition and patterning of copper.

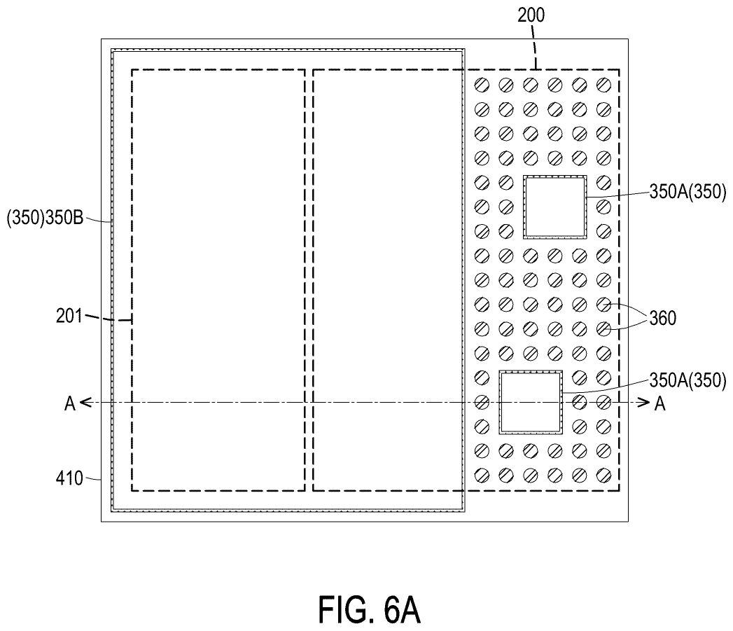

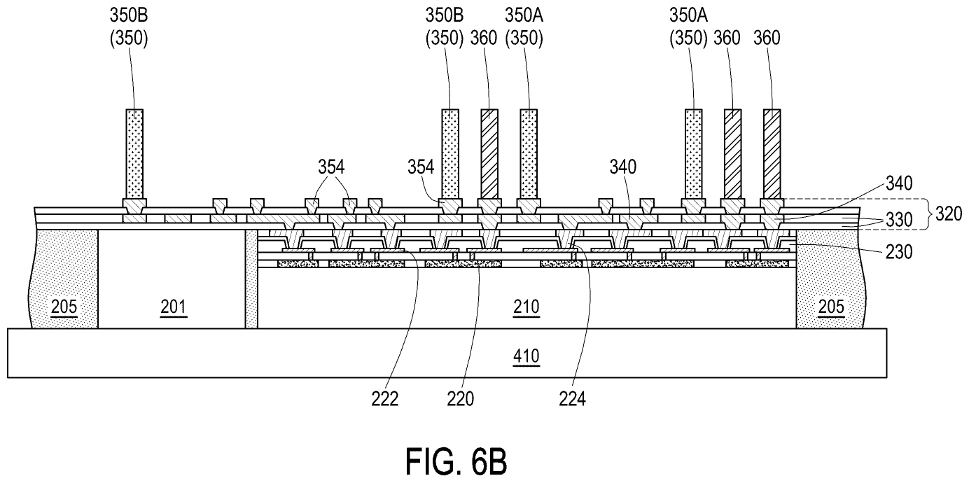

Referring to FIGS. 6A and 6B, FIG. 6A is a schematic top view of an exemplary structure of FIG. 6B, and FIG. 6B is a cross-sectional view along a cross-sectional line A-A of FIG. 6A. Following FIG. 5, referring to FIG. 6B, ring walls 350 and pillars 360 are formed on the first redistribution structure 320, and some of the ring walls 350 and all of the pillars 360 are formed directly on the first pedestal patterns 354 by deposition and patterning of a conductive material. In some embodiments, the ring walls 350 include ring walls 350A and at least one ring wall 350B, and the ring walls 350A and the ring wall(s) 350B are formed with different dimensions and/or of different shapes. In some other embodiments, the ring walls 350 and/or the pillars 360 are pre-formed and transferred onto the first redistribution structure 320.

In FIG. 6A, the first pedestal patterns 354 are not shown for simplicity, the pillars 360 are arranged as an array with the ring walls 350A located inside the array, and the pillars 360 are located beside and around each ring walls 350A. In FIG. 6A, from the top view, the ring wall 350A or the ring wall 350B is formed as a rectangular shaped frame structure that continuously extends and encircles a region without pillars 360 located within the encircled region. Referring to FIG. 6A, the span of the ring wall 350B or the area enclosed by the ring wall 350B is partially overlapped with the area of the below dummy die 201 and is partially overlapped with the area of the below semiconductor die 200. That is, from the schematic top view, the below dummy die 201 is fully encircled by the ring wall 350B, and a portion of the below semiconductor die 200 is enclosed by the ring wall 350B. In some embodiments, the span or the enclosed area of the ring wall 350A is smaller than that of the ring wall 350B. For example, the size and the shape of the ring wall 350A may be designed according to the size and outline of the to-be-mounted device such as one or more passive device dies.

The formation of the pillars 360 and the ring walls 350 may involve applying a masking pattern (not shown) such as a photoresist pattern with openings and ring trenches respectively corresponding to the later formed pillars 360 and the ring walls 350, and forming a metallic fill material filling in the openings and ring trenches to form the pillars 360 and the ring walls 350. In some embodiments, before forming the metallic material, a metallic barrier material is formed over the masking pattern as the barrier. For example, the materials of the pillars 360 and the ring walls 350 include one or more metallic materials of tungsten (W), titanium (Ti), tantalum (Ta), molybdenum (Mo), ruthenium (Ru), cobalt (Co), copper (Cu), nitrides thereof, alloys thereof or combinations thereof. In this embodiment, the first pedestal patterns 354 may have suitable lateral dimensions (such as dimensions in a range from 10 μm to 60 μm) for accommodating the pillars 360 and the ring wall 350. The ring wall 350 may have substantially the same height as the pillars 360. In one embodiment, the pillars 360 are electrically connected to the semiconductor die(s) 200 through the first redistribution patterns 340 and through the first pedestal patterns 354. The ring walls 350 including the ring walls 350A and 350B are disposed on the first pedestal patterns 354 but are not electrically connected with the semiconductor die(s) 200.

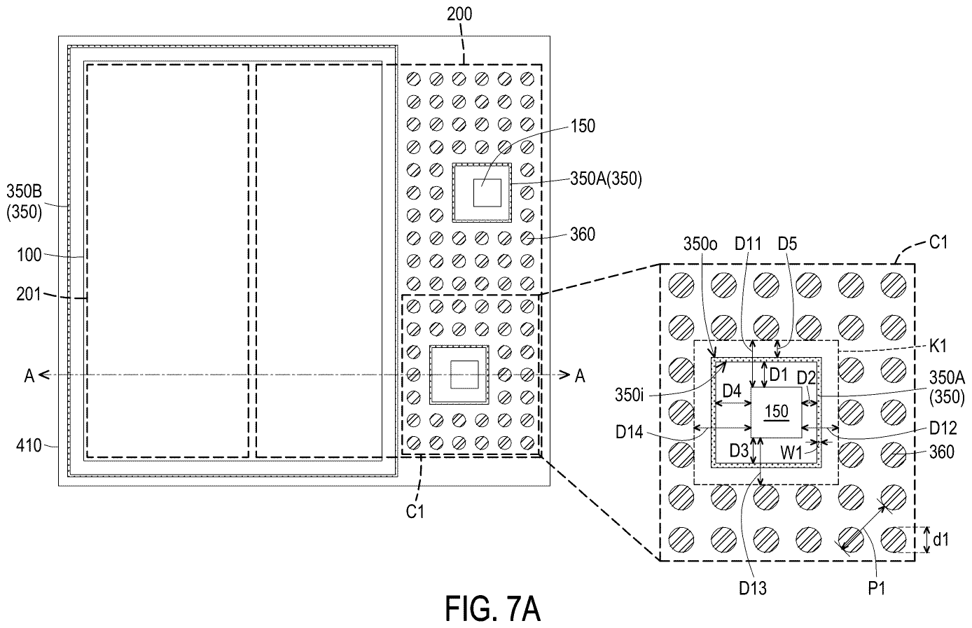

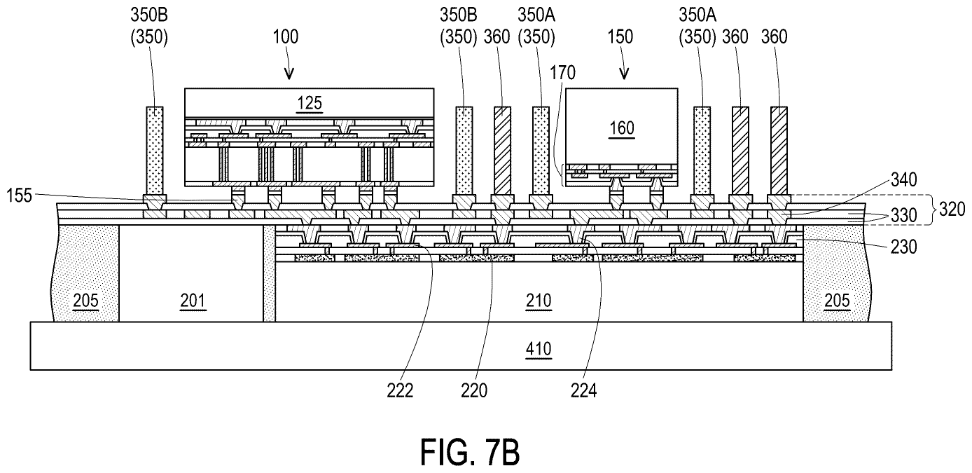

Referring to FIGS. 7A and 7B, FIG. 7A is a schematic top view of FIG. 7B, and FIG. 7B is a schematic cross-sectional view of the line A-A of FIG. 7A. Referring to FIGS. 7A and 7B, TSV dies 100 and passive device dies 150 are mounted onto and bonded to the first redistribution structure 320 and located over the semiconductor dies 200 and the dummy dies 201. In some embodiments, the TSV dies 100 are similar to or substantially the same as the TSV die described in FIG. 3.

In FIG. 7A, the TSV die 100 is located within the enclosed region of the ring wall 350B, and the passive device dies 150 are each disposed within one of the ring walls 350A. An enlarged view at the right part of FIG. 7A illustrates a region C1 including the pillars 360, one of the ring walls 350A and the passive device die 150. In some embodiments, the pillars 360 are spaced apart from one another with a pitch P1 (between any two adjacent pillars 360) in a range from 10 μm to 100 μm, such as 80 μm, although lesser and greater dimensions may also be used. In some embodiments, using round or oval pillars as examples, a diameter of a maximum lateral dimension d1 of each pillar 360 may be in a range from 10 μm to 80 μm, such as 40 μm, although lesser and greater dimensions are applicable. In some embodiments, the ring wall 350A and the ring wall 350B may be formed with the same uniform wall thickness (as width from the top view) W1. Referring to the enlarged view at the right part of FIG. 7A, the width W1 of the ring wall 350A may be in a range about 5 μm to about 60 μm, such as 10 μm to about 20 μm. In some other embodiments, the ring wall 350A is formed with a wall thickness smaller than that of the ring wall 350B.

In some embodiments, the passive device die 150 is separate and spaced apart from the ring wall 350A with distances D1-D4 (distances between four sides of the passive device die 150 and the corresponding four inner sides 350i of the ring wall 350A). Either of the distances D1, D2, D3 and D4 may be in a range of about 10 μm to about 200 μm, such as about 20 μm to about 180 μm. In one embodiment, as seen in the enlarged view, the distance D4 is larger than the distances D1-D3 since a dispensing space is reserved for the application of a dispenser for later dispensing an underfill into a gap between the passive device die 150 and the inner side(s) 350i of the ring wall 350A. For example, the distance D4 is larger than the distance D1, and the distances D1, D2 and D3 are about the same, and a ratio of D4/D1 is about 9. If considering placing the dispenser at a specific position (dispensing site) along the distance D4, a ratio of a distance between the dispensing site and the passive device die 150 to a distance between a dispensing site and the nearest inner side 350i of the ring wall 350A may be about 4:5.

As seen in the enlarged view of FIG. 7A, a keep out zone (KOZ) K1 is illustrated by the dashed line outside the ring wall 350A, and the keep out zone K1 is the pillar-free region (blank region or void zone) between the passive device die 150 and the surrounding pillars 360 for keeping the ring wall 350A separate from the pillars 360. As the ring wall 350A is separate and spaced apart from the pillars 360, the keep out zone K1 may be defined by a distance D5 (the shortest distance between an outer side 350o (opposed to the inner side 350i) of the ring wall 350 and the nearest pillar 360. The distance D5 may be in a range of about 10 μm to about 50 μm, such as from about 20 μm to about 40 μm. Distances D11 to D14 are distances between four sides of the passive device die 150 to the virtual outline of the keep out zone K1. Either of the distances D11 to D14 may be in a range of about 60 μm to about 260 μm, such as from about 80 μm to about 240 μm. In some embodiments, as seen in FIG. 7A, the distance D14 is larger than the distances D11-D13.

In FIG. 7A and FIG. 7B, the TSV die 100 is located beside the ring wall 350B and bonded to the first pedestal patterns 354 of the first redistribution structure 320 through micro-connectors 146, and the passive device dies 150 are disposed within the ring walls 350A and bonded to the first pedestal patterns 354 of the first redistribution structure 320 through micro-connectors 146. The passive device die 150 may include a passive device layer 160 including a plurality of passive devices and an interconnect structure 170 formed thereon. The passive devices may be or include capacitors such as embedded deep trench capacitors (eDTC), resistors, inductors, or the like. The TSV die(s) 100 and the passive device die(s) 150 are electrically connected with the below semiconductor dies 200 via the first pedestal patterns 354 and the first redistribution structure 320.

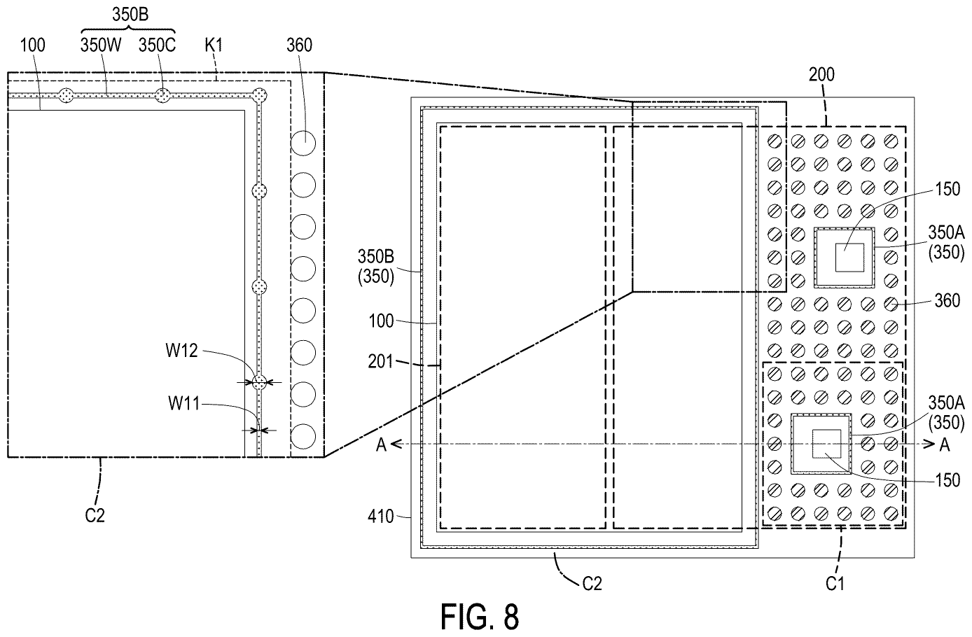

Referring to FIG. 8, FIG. 8 illustrates another configuration, column-and-wall configuration, of the ring walls 350. At the left part of FIG. 8, an enlarged view showing a portion of the region C2 including portions of the ring wall 350 and the TSV die 100. Except for the further description, the definition of the reference symbols and labeled representations are the same as FIG. 7A, and will not be repeated herein. Although the ring wall 350 with such configuration is arranged around the region C2, it is understood that the ring wall 350 of such configuration may be arranged in the region C1 around the passive device die 150.

In FIG. 8, the ring wall 350 is formed with a column-and-wall configuration, and the ring wall 350 (for example, the ring wall 350) includes column portions 350C connected by wall portions 350W. As seen in FIG. 8, the wall portion 350W may be shaped as a wall structure with a first width W11 (from the top view, perpendicular to the extending length) and the column portion 350C may have a shape of a round or oval column of a second diameter (width) W12. For example, for the ring wall 350 with the column-and-wall configuration, the first width W11 and the second width W12 are different, and the second width W12 is larger than the first width W11. The first width W11 of the ring wall 350 may be in a range about 5 μm to about 100 μm, such as 10 μm to about 20 μm, although lesser and greater dimensions may also be used. The second width W12 of the ring wall 350 may be in a range about 5 μm to about 100 μm, such as 10 μm to about 20 μm, although lesser and greater dimensions may also be used. For the ring wall 350 with a column-and-wall configuration, the column portions 350C of the ring wall 350 have larger widths, which further strengthens the rigidity of the ring wall 350 and improve the mechanical strength of the package structure.

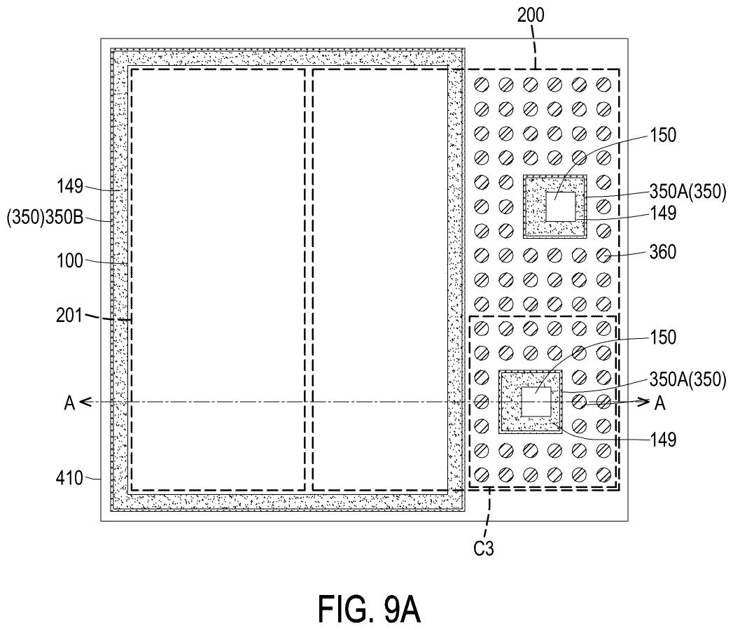

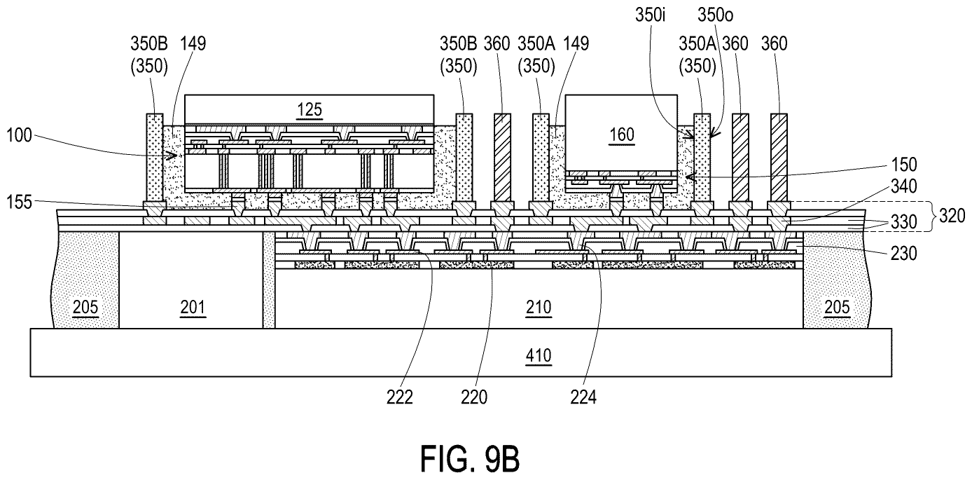

Referring to FIGS. 9A and 9B, FIGS. 9A and 9B are continued from FIGS. 7A and 7B. FIG. 9A is a top view of FIG. 9B, and FIG. 9B is a cross-sectional view of the line A-A of FIG. 9A.

An underfill 149 is disposed between the TSV die 100 and ring wall 350 and between the TSV die 100 and the first redistribution structure 320. The formation of the underfill 149 involves is applying the underfill 149 to a first gap between the TSV die 100 and the ring wall 350 and between the TSV die 100 and the first redistribution structure 320, and a second gap between each passive device die 150 and the corresponding ring wall 350. passive device die 150 The first gap and the second gap may also be filled by the underfill 149. The underfill 149 spread in a space between ring wall 350 and the TSV die 100 and passive device die 150. The ring walls 350 may block the underfill 149, prevent the underfill 149 spreading to the pillars 360 and prevent the underfill 149 in contact with the pillars 360. The first pedestal patterns 354, the micro-connectors 146 and the solder material portions 148 may laterally surrounded by the underfill 149 spreading in a space between the first redistribution structure 320 and the TSV die 100 and passive device die 150. The underfill 149 is applied in a suitable amount. The underfill 149 may be formed of any suitable material, such as epoxy polymer. In other embodiments, the underfill 149 may include inorganic fillers.

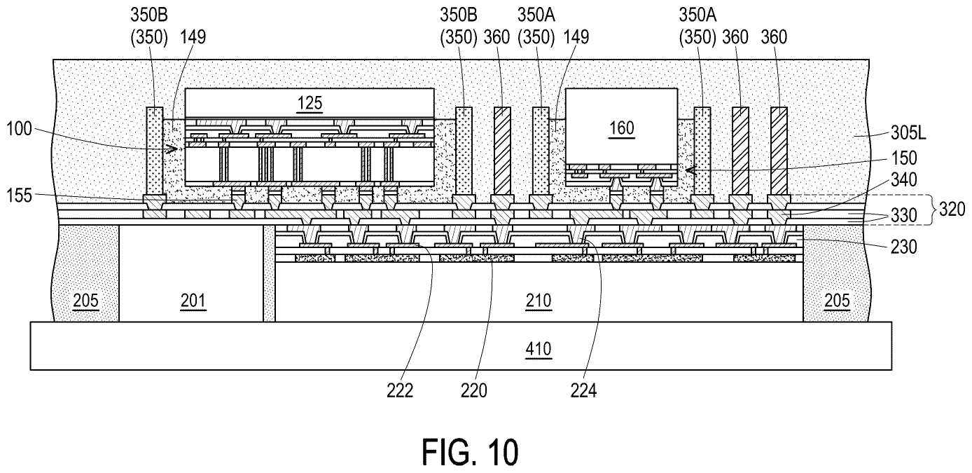

Referring to FIG. 10, an encapsulant material 305L is around and above the TSV die 100, the passive device die 150, the ring walls 350 and the pillars 360. The formation of the encapsulant material 305L involves applying the encapsulant material 305L into spaces between each TSV die 100, the passive device die 150, each ring wall 350, and each pillar 360 until covering on top surfaces of the TSV die 100, the passive device die 150, the ring walls 350, and pillars 360. The encapsulant material 305L may be a molding compound, a molding underfill (MUF), a resin (such as epoxy), or the like. The encapsulant material 305L may be different from the material of the underfill 149. In other embodiments, encapsulant material 305L may include inorganic fillers having a particle size greater than a particle size of the inorganic fillers of the underfill 149.

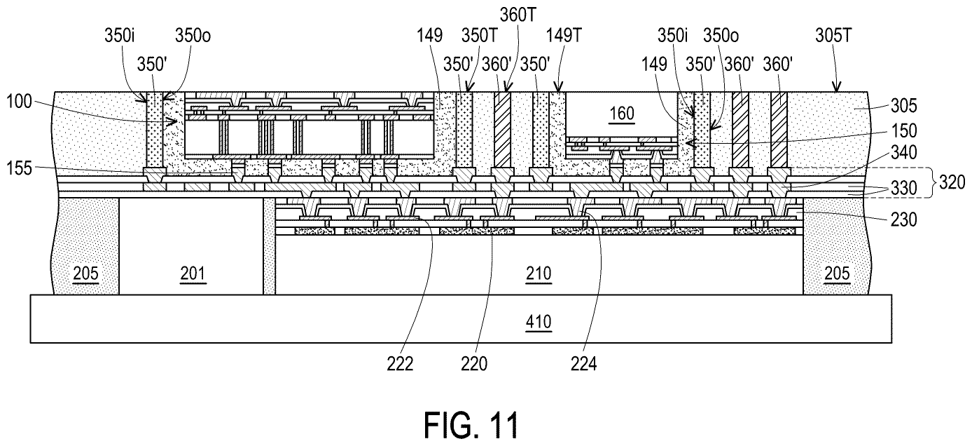

Referring to FIG. 11, a second encapsulant 305 is disposed on the first redistribution structure 320 and the underfill 149, and laterally wrapping around the TSV die 100, the passive device dies 150, TIV walls 350′, and TIVs 360′. The formation of the second encapsulant 305, the TIV walls 350′, and the TIVs 360′ involves performing a thinning process to partially remove the encapsulant material 305L, the ring walls 350, the pillars 360 until the contact pads 1246 of the TSV die 100 are exposed for electrical connect. The thinning process includes performing an etching process, a grinding process or a chemical mechanical polishing (CMP) process, for example.

Top surfaces of the TSV dies 100, the passive device dies 150, the TIV walls 350′, and the TIVs 360′ are exposed after the thinning process. A top surface 149T of the underfill 149 may substantially align with a top surface 350T of the TIV wall 350′, top surfaces 360T of the TIVs 360′, and a top surface 305T of the second encapsulant 305.

The underfill 149 extends along the inner side 350i of the TIV wall 350′, and extends between the inner sides 350i of two adjacent TIV walls 350′. The second encapsulant 305 may extends along the outer side 350o of the TIV wall 350′, extends between the outer side 350 o of the TIV wall 350′ and the TIVs 360′, and extends between two adjacent TIVs 360′.

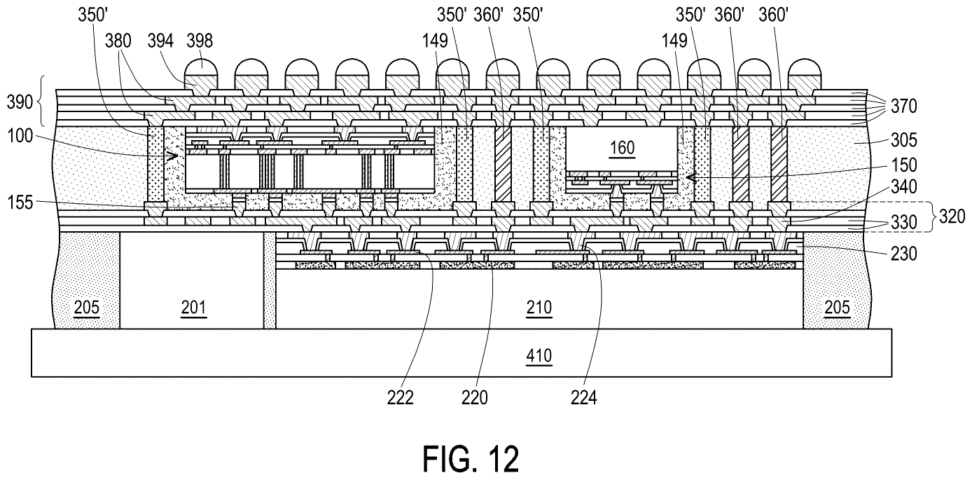

Referring to FIG. 12, a second redistribution structure 390 is formed over the TSV die 100, the passive device die 150, the TIV walls 350′, the TIVs 360′, and the second encapsulant 305. The second redistribution structure 390 includes second redistribution patterns 380 formed within second redistribution dielectric layers 370. The processing steps may be the same as the first redistribution structure 320. In one embodiment, the TIVs 360′ may be electrically connected to a respective one of the second redistribution patterns 380 upon formation of the second redistribution patterns 380. In some embodiments, the TIV walls 350′ are electrical grounded and electrical floating. In some embodiments, the TIV walls 350′ may be connected to a shielding component for electromagnetic shielding.

Second pedestal patterns 394 may be formed at the topmost level of the second redistribution structure 390. The second pedestal patterns 394 may be formed by deposition and patterning of a metallic bonding material. In one embodiment, the second pedestal patterns 394 may be formed by deposition and patterning of a metallic material. In one embodiment, the first pedestal patterns 354 may include copper bump structures that are formed by deposition and patterning of copper. The second pedestal patterns 394 may be formed as microbump structures configured for chip connection (C2) bonding, or as metallic bonding pads configured for controlled-collapse chip connection (C4) bonding. Solder material portions 398 may be attached to the second pedestal patterns 394.

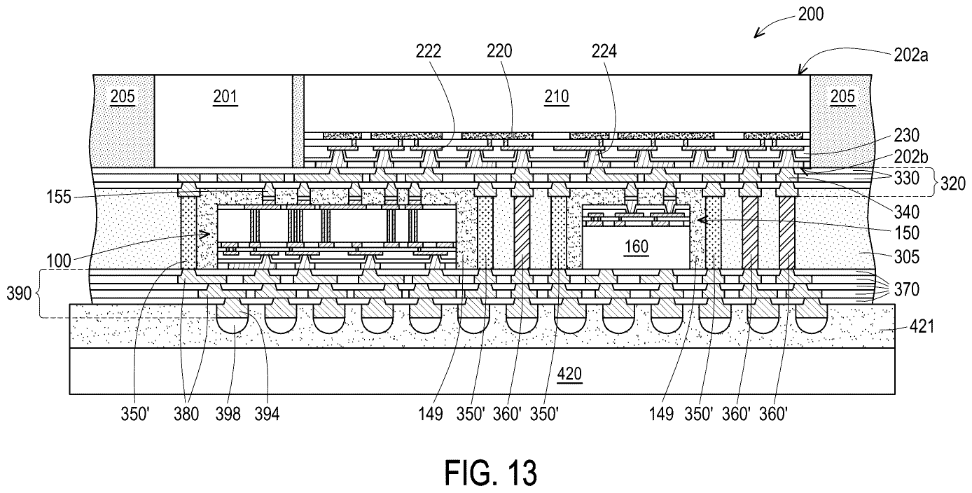

Referring to FIG. 13, the reconstituted wafer of FIG. 12 is disposed on a second temporary carrier 420 through an adhesive layer 421. Then adhesive layer 421 may be applied over the second pedestal patterns 394 and the solder material portions 398. The second temporary carrier 420 may be attached to the reconstituted wafer of FIG, 12 through the adhesive layer 421. The first temporary carrier 410 may be detached from the reconstituted wafer by inducing decomposition of the die attachment film (not shown). The physically exposed backside surface of the dummy die 201 and the backside surface 202a of the semiconductor die 200 may be thinned, for example, by grinding or polishing. A suitable cleaning process may also be performed on the backside surface of the dummy die 201 and the backside surface 202a of the semiconductor die 200 after the thinning process.

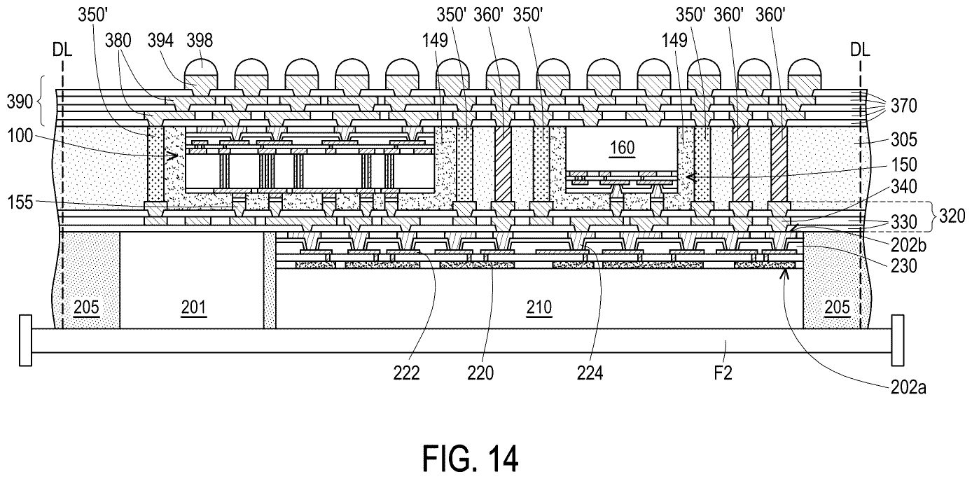

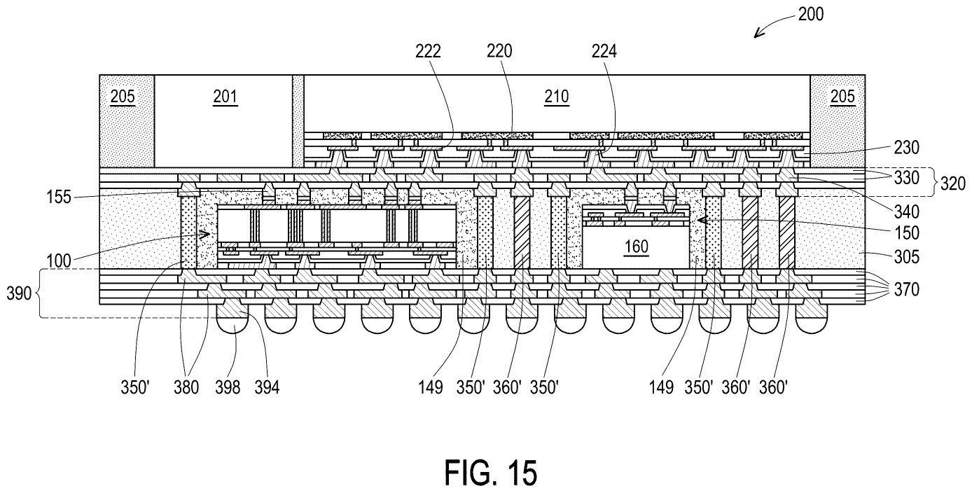

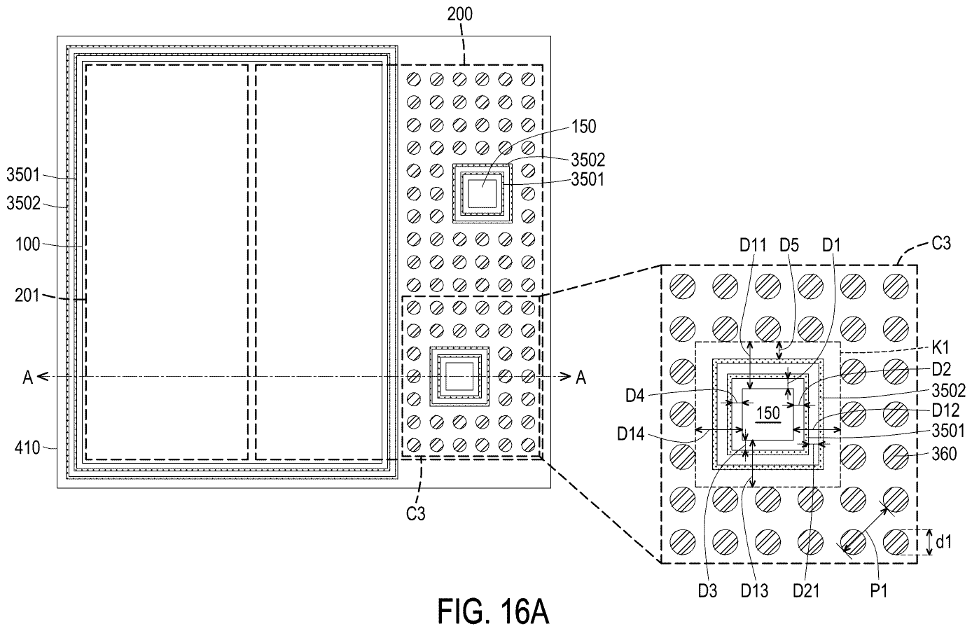

Referring to FIG. 14, a frame F2 is disposed on the backside surface of the dummy die 201 and the backside surface 202a of the semiconductor die 200. The frame F2 may be mounted to the backside surface of the dummy die 201 and the backside surface 202a of the semiconductor die 200 and the adhesive layer 421 may be decomposed, for example, by applying heat. In one embodiment, the exemplary structure may be annealed above the decomposition temperature of the material of the adhesive layer 421, which may be in a range from 200 degrees Celsius to 250 degrees Celsius. The second temporary carrier 420 is detached from the reconstituted wafer. Then, the reconstituted wafer is diced along dicing lines DL to form a package structure shown in FIG. 15.

Referring to FIG. 15, the package structure is formed after singulation. Physically exposed sidewalls of various components of the package structure may be vertically coincident (i.e., located within a same vertical plane) because all components of the package structure are provided through dicing of the reconstituted wafer.

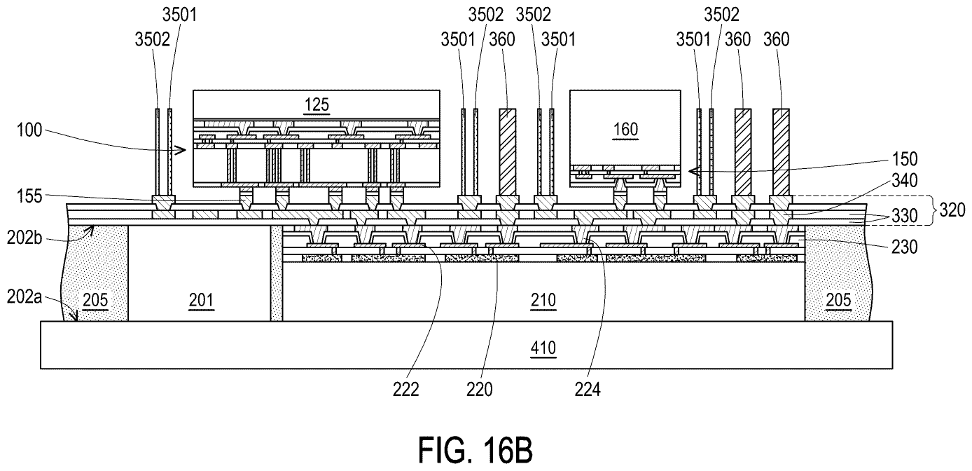

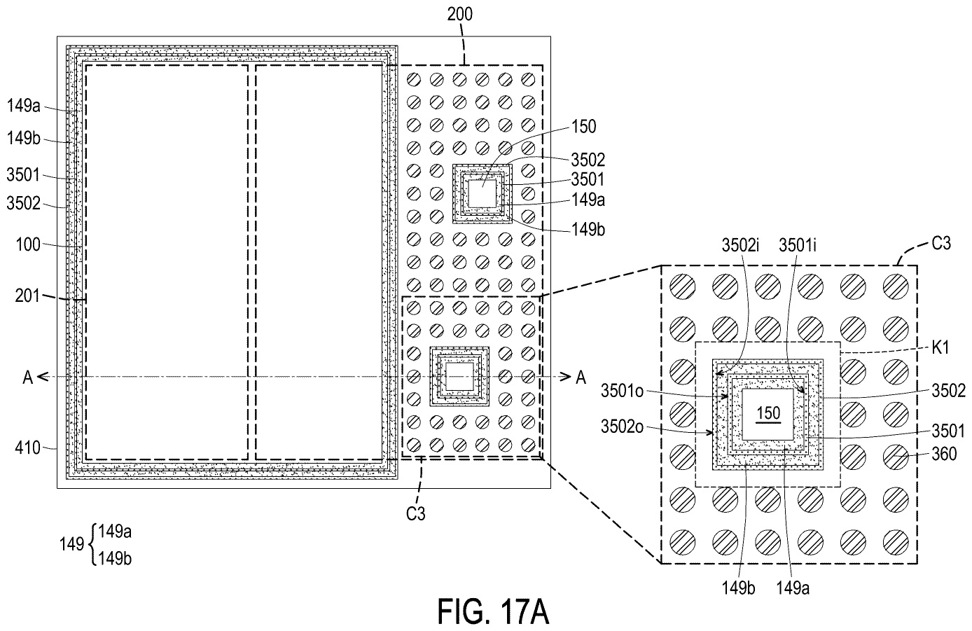

FIG. 16A to FIG. 20 are schematic top views and cross-sectional views illustrating various stages of the formation method of a package structure in accordance with some embodiments of the present disclosure

Referring to FIGS. 16A and 16B, FIG. 16A is a top view of FIG. 16B, and FIG. 16B is a cross-sectional view of the line A-A of FIG. 16A. Except for the further description, the definition of the reference symbols and labeled representations of FIGS. 16A and 16B are the same as FIG. 1 to FIG. 15, and will not be repeated herein.

The TSV die 100 (shown in FIG. 3) and the passive device die 150 is each disposed within one of first ring walls 3501, and each one of the first ring walls 3501 is surrounded by a second ring wall 3502. An enlarge view enlarges a region C3 including one of the first ring walls 3501, one of the second ring walls 3502 and the passive device die 150. The passive device die 150 may be disposed within the first ring wall 3501. The first ring wall 3501 may be around the passive device die 150, and the second ring wall 3502 may be around the first ring wall 3501. In other embodiment, the enlarge view is also applicable to a region including one of the first ring walls 3501, one of the second ring wall 3502, and the TSV die 100.

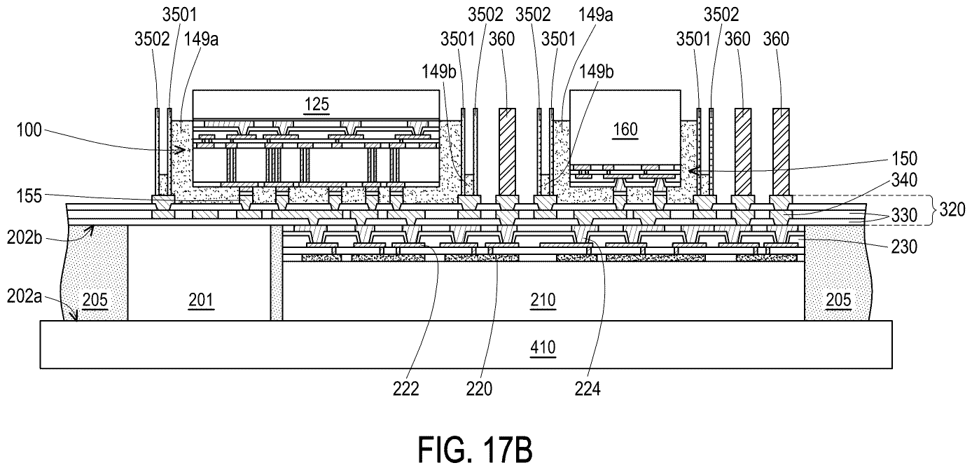

Distances D1 to D4 may be distances between four sides of the passive device die 150 and the corresponding inner side 3501i (shown in FIG. 17A) of the first ring wall 3501. For example, the distance D4 may be greater than the distances D1 to D3 since an enough dispensing space is needed for a dispenser dispensing a underfill into a gap between the passive device die 150 and the inner side 3501i of the first ring wall 3501. A ratio of a distance between a dispensing site and the passive device die 150 to a distance between a dispensing site and the inner side 3501 i of the first ring wall 3501 may be about 4:5.

A distance D5 is a shortest distance between an outer side 3502o (shown in FIG. 17A) of the second ring wall 3502 and the corresponding the pillars 360. A periphery of a keep out zone (KOZ) K1 is presented by a dashed line. The keep out zone K1 is defined by a region between the passive device die 150 and the pillars 360. A distance D21 between the outer side 3501o of the first ring wall 3501 and the inner side 3502 i of the second ring wall 3502 may be in a range of about 10 μm to about 50 μm, such as about 20 μm or less, although lesser and greater distances may also be used.

In FIG. 16B, each one of the first ring walls 3501 and each one of the second ring walls 3502 is disposed on the first pedestal patterns 354. The formation of the first ring walls 3501 and-the second ring walls 3502 are formed by deposition and patterning of a conductive material, or by transfer from above another temporary carrier.

Referring to FIGS. 17A and 17B, FIG. 17A is a top view of FIG. 17B, and FIG. 17B is a cross-sectional view of the line A-A of FIG. 17A. Except for the further description, the definition of the reference symbols and labeled representations of FIGS. 17A and 17B are the same as FIG. 1 to FIG. 16B, and will not be repeated herein.

In FIGS. 17A and 17B, an underfill 149 is disposed between the TSV die 100 and the first ring wall 3501 and between the TSV die 100 and the first redistribution structure 320, and disposed between the passive device die 150 and the first ring wall 3501 and between the passive device die 150 and and the first redistribution structure 320, and disposed between the first ring wall 3501 and the second ring walls 3502. The formation of the underfill 149 involves applying the underfill 149 to a first gap between the TSV die 100 and the inner side 3501i of the first ring wall 3501, and second gap between each one of the passive device dies 150 and the inner side 3501i of the corresponding one of the first ring walls 3501. The first to second gaps may also be each filled by a first portion 149a of the underfill 149 spreading in a space between the inner side 3501i of the first ring wall 3501 and the TSV die 100 and the passive device die 150. Some underfill 149 (e.g. a second portion 149b of the underfill 149) may leak out from the first to second gaps, and spread in a space between the outer side 3501o of the first ring wall 3501 and the inner side 3502i of the second ring walls 3502. The second ring walls 3502 may block the underfill 149 (e.g. the second portion 149b of the underfill 149) and prevent the underfill 149 spreading to the pillars 360 and in contact with the pillars 360.

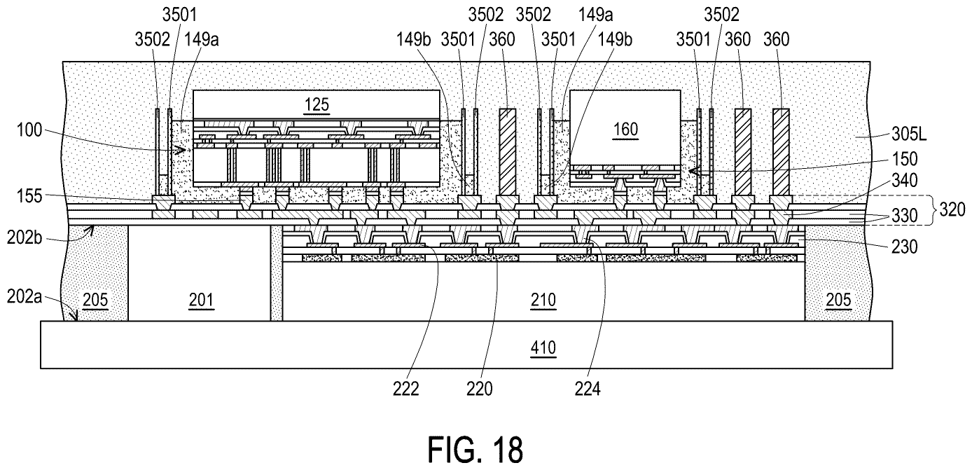

Referring to FIG. 18, except for the further description, the definition of the reference symbols and labeled representations of FIG. 18 are the same as FIG. 1 to FIG. 17B, and will not be repeated herein.

An encapsulant material 305L is disposed around and above the TSV die 100, the passive device die 150, the first ring wall 3501 and the second ring walls 3502 and the pillars 360. The encapsulant material 305L is disposed on the first portions 149a of the underfill 149 and the second portions 149b of the underfill 149 between the first ring walls 3501 and the second ring walls 3502. The formation of the encapsulant material 305L involves applying the encapsulant material 305L into spaces between the TSV die 100, the passive device die 150, the first ring walls 3501, the second ring walls 3502, and the pillars 360 until covering on top surfaces of the TSV die 100, the passive device die 150, the first ring wall 3501 and the second ring walls 3502, and pillars 360.

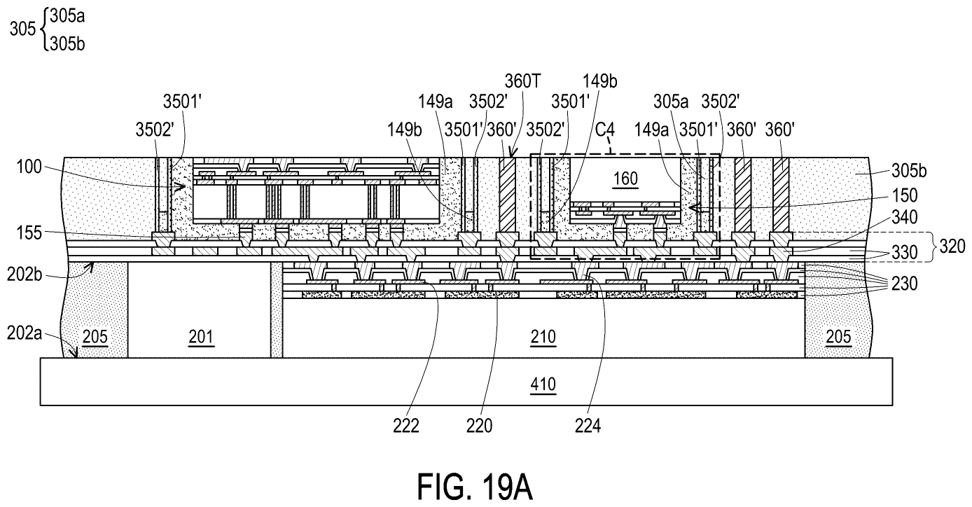

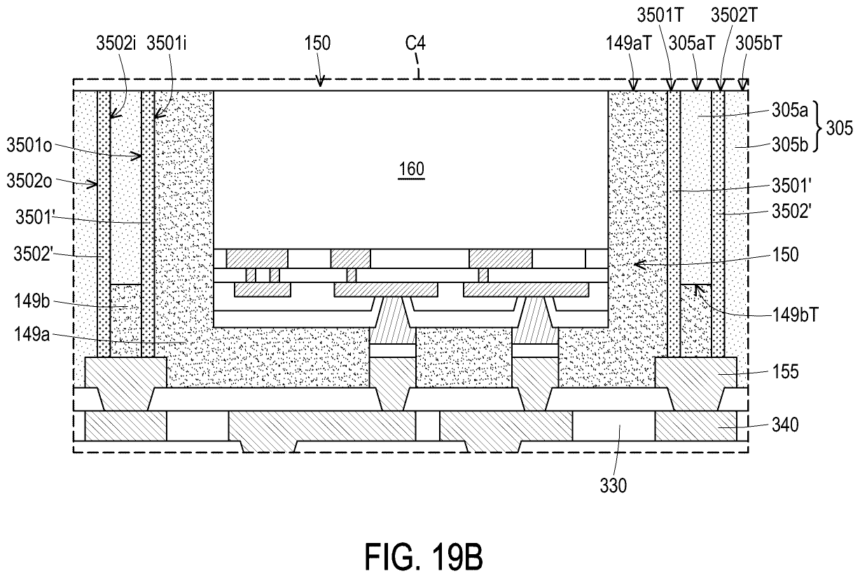

Referring to FIGS. 19A and 19B, except for the further description, the definition of the reference symbols and labeled representations of FIGS. 19A and 19B are the same as FIG. 1 to FIG. 18, and will not be repeated herein.

In FIG. 19A, a second encapsulant 305 is disposed on the first redistribution structure 320 and the first to second portions 149a, 149b of the underfill 149, and laterally wrapping around the TSV die 100, the passive device dies 150, first TIV walls 3501′, second TIV walls 3502′, and the TIVs 360′. The formation of the second encapsulant 305, first TIV walls 3501′, second TIV walls 3502′ and the TIVs 360′ involves performing a thinning process to partially remove the encapsulant material 305L, the first to second ring walls 3501, 3502, the pillars 360 until the contact pads 1246 of the TSV die 100 are exposed for electrical connect. The thinning process includes performing an etching process, a grinding process or a chemical mechanical polishing (CMP) process, for example.

In FIG. 19B, FIG. 19B is an enlarge view enlarging a region C4 of FIG. 19A. The region C4 includes the first TIV walls 3501′, the second TIV walls 3502′, and the passive device die 150. The second encapsulant 305 includes first portions 305a disposed between the first TIV walls 3501′ and the second TIV walls 3502′, and second portions 305b laterally surrounding the second TIV walls 3502′ and the TIVs 360′. The first portions 305 a of the second encapsulant 305 is disposed on the second portion 149b of the underfill 149.

After thinning process, a top surface 149aT of the first portion 149a of the underfill 149 may align with top surfaces 3501T of the first TIV walls 3501′, top surfaces 3502T of the second TIV wall 3502′, top surfaces 305aT of the first portions 305a of the second encapsulant 305, and top surfaces 305bT of the second portions 305b of the second encapsulant 305.

A level of the top surface 149aT of the first portion 149a of the underfill 149 may be higher than a level of each top surfaces 149bT of the second portions 149b of the underfill 149. Each the second portions 149b of the underfill 149 may be in contact with the first portions 305 a of the second encapsulant 305 at a contact interface between the outer side 3501o of the first TIV walls 3501′ and the inner side 3502i of the second TIV walls 3502′. A level of each one of the top surfaces 149aT, 3501T, 3502T, 305aT, 305bT may be higher than a level of the contact interface.

Each first portions 149a of the underfill 149 extends along the inner side 3501i of the first TIV wall 3501′ and surrounds the passive device die 150. Each second portions 149b of the underfill 149 extends along the outer side 3501o of the first TIV wall 3501′ and the inner side 3502i of the second TIV wall 3502′.

In other embodiments, a level of the top surface 149aT of the first portion 149a of the underfill 149 may equal to a level of each top surfaces 149bT of the second portions 149b of the underfill 149. In other embodiments, a level of each one of the top surfaces 149aT, 3501T, 3502T, 305bT may aligns with top surfaces 149bT of the second portions 149b of the underfill 149.

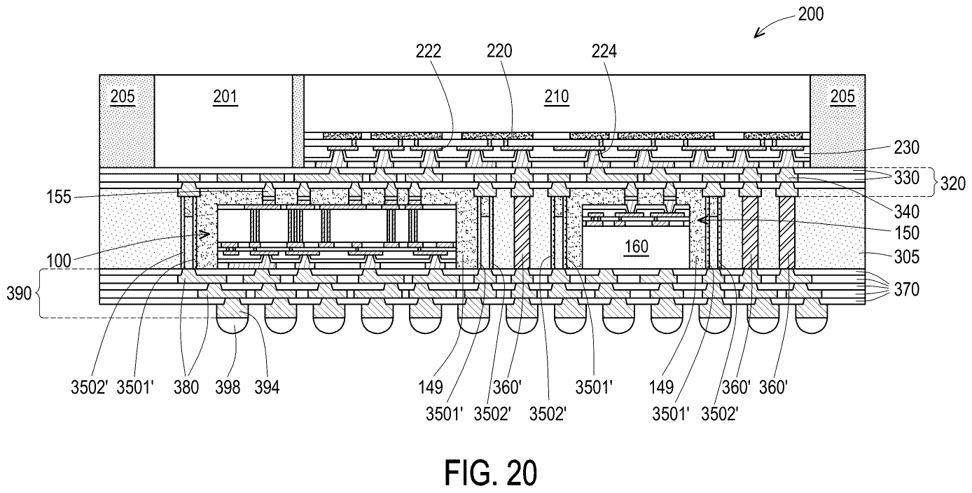

Referring to FIG. 20, except for the further description, the definition of the reference symbols and labeled representations of FIG. 20 are the same as FIG. 1 to FIG. 19, and will not be repeated herein.

Referring to FIG. 20, a package structure is formed after singulation. Physically exposed sidewalls of various components of the package structure may be vertically coincident (i.e., located within a same vertical plane) because all components of the package structure are provided through dicing of the reconstituted wafer. The second redistribution structure 390 may be formed over the TSV die 100, the passive device die 150, the first TIV walls 3501′, the second TIV walls 3502′, the TIVs 360′, and the second encapsulant 305. In one embodiment, the first TIV walls 3501′ and the second TIV walls may be each electrical grounded and electrical floating. In one embodiment, the first TIV walls 3501′ and the second TIV walls may be each connected to shielding components for electromagnetic shielding.

A package structure and a method of forming the package structure are provided. The package structure includes a die, a TIV wall around the die, an array of TSVs around the TIV wall. A top surface of the TIV wall substantially aligns with top surfaces of the TIVs. When an underfill is applied to a gap between the die and the TIV wall, the TIV wall blocks the spread of the underfill. Thus, the TIV wall prevents the underfill spreading to the TSVs, so as to reduce the impact of the underfill spread on TSV signaling. Besides, the keep out zone (KOZ) between the die and the TSVs is also reduced since the span of the underfill is limited by the TIV wall. As a result, the TIV depopulation is mitigated, the Power Delivery Network (PDN) performance is improved, the limitation of the I/O design, the P/G design and the routability of the TIVs is decreased, and the cost is lowered.

In accordance with some embodiments of the present disclosure, a package structure is provided. The package structure includes a first die, a first redistribution structure, a second die, a TIV wall, an array of TIVs, an underfill, and an encapsulant. The first redistribution structure is disposed on an active surface of the first die. The second die is disposed on the first redistribution structure and over the active surface of the first die. The second die is electrically connected to the first die through the first redistribution structure. The TIV wall is disposed on the first redistribution structure, beside the second die, spaced apart from and encircling the second die. The TIV wall is electrically floating. The array of the TIVs is disposed on the first redistribution structure and beside and surrounding the TIV wall and the second die, and electrically connected to the first die. The underfill is disposed between the second die and the TIV wall and between the second die and the first redistribution structure. The encapsulant is disposed on the first redistribution structure and laterally wraps around the second die, the TIV wall and each of the array of the TIVs.

In accordance with some embodiments of the present disclosure, a package structure is provided. The package structure includes a first die having an active surface, a first redistribution structure, TIVs, a TIV wall, a second die, an underfill, and an encapsulant. The first redistribution structure is disposed on the active surface of the first die. The TIVs are disposed on the first redistribution structure, and electrically connected to the first die. The TIV wall is disposed on the first redistribution structure, located beside, and spaced apart from the TIVs. The second die is disposed on the first redistribution structure, over the active surface of the first die, and disposed within the TIV wall. The TIV wall is electrically unconnected with the first die. The underfill is disposed between the second die and the TIV wall and between the second die and the first redistribution structure. The encapsulant is disposed on the first redistribution structure and laterally wraps around the second die, the TIV wall and the TIVs. A material of the underfill is different from a material of the encapsulant.

In accordance with some embodiments of the present disclosure, a method of forming a package structure is provided. A first die is provided. A redistribution structure is formed on an active surface of the first die. TIV wall is formed on the redistribution structure. The TIV wall is electrically floating. An array of TIVs is formed on the redistribution structure and beside and surrounding the TIV wall. The array of TIVs are electrically connected to the first die, A second die is placed on the redistribution structure, over the active surface of the first die and within the TIV wall from a top view. The second die is electrically connected to the first die through the redistribution structure. The TIV wall is beside the second die, spaced apart from and encircles the second die. An underfill is applied to a first gap between the second die and the TIV wall and between the second die and the redistribution structure. An encapsulant material laterally wraps the second die, the TIV wall and each of the array of the TIVs on the redistribution structure. A planarization process is performed on the second die, the TIV wall, each of the array of the TIVs and the encapsulant material, to form an encapsulant laterally wrapping around the second die, the TIV wall and each of the array of the TIVs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first die;
a first redistribution structure disposed on an active surface of the first die;
a second die disposed on the first redistribution structure and over the active surface of the first die, wherein the second die is electrically connected to the first die through the first redistribution structure;
a through insulator via (TIV) wall disposed on the first redistribution structure, spaced apart from and encircling the second die, wherein the TIV wall is electrically floating;
an array of through insulator vias (TIVs), disposed on the first redistribution structure and surrounding the TIV wall and the second die, and electrically connected to the first die;
an underfill disposed between the second die and the TIV wall and between the second die and the first redistribution structure; and
an encapsulant disposed on the first redistribution structure and laterally wrapping around the second die and the TIV wall.

2. The package structure of claim 1, wherein
the TIV wall is beside the second die,
the array of the TIVs is beside the TIV wall and the second die,
the encapsulant laterally wraps around each of the array of the TIVs, and
the underfill is in contact with an inner side of the TIV wall and the second die, and a top surface of the underfill is substantially levelled with a top surface of the TIV wall and top surfaces of the TIVs.

3. The package structure of claim 2, wherein the encapsulant extends along an outer side of the TIV wall without contacting the second die, and a top surface of the encapsulant is substantially levelled with the top surface of the underfill.

4. The package structure of claim 1, wherein the TIV wall comprises:
a first TIV wall located beside the second die, spaced apart from and encircling the second die, and
a second TIV wall located beside the first TIV wall, spaced apart from and encircling the first TIV wall.

5. The package structure of claim 4, wherein the underfill comprises:
a first portion, disposed between the second die and the first TIV wall, and
a second portion, disposed between the first TIV wall and the second TIV wall, and
wherein a top surface of the first portion of the underfill is higher than a top surface of the second portion of the underfill.

6. The package structure of claim 1, wherein the TIV wall comprises column portions and wall portions connecting the column portions, and a first width of the column portions is different from a second width of the wall portions from a top view.

7. The package structure of claim 1, further comprising:
a third die, disposed on the first redistribution structure over the first die, electrically connected to the first die, and beside the TIV wall and the second die;
an additional TIV wall disposed on the first redistribution structure, spaced apart from and beside the third die, and encircling the third die; and
an additional underfill disposed between the third die and the additional TIV wall,
wherein the encapsulant laterally wraps around the additional TIV wall and the third die.

8. The package structure of claim 1, further comprising:
a second redistribution structure disposed on the TIV wall and on the array of the TIVs and on the second die wrapped by the encapsulant and above the first die; and
conductive connectors, disposed on the second redistribution structure, and electrically connected to the first die and the second die through the first and second redistribution structures and the array of the TIVs.

9. A package structure, comprising:
a first die having an active surface;
a first redistribution structure disposed on the active surface of the first die;
through insulator vias (TIVs) disposed on the first redistribution structure, and electrically connected to the first die;
a TIV wall disposed on the first redistribution structure, located beside, and spaced apart from the TIVs;
a second die disposed on the first redistribution structure, over the active surface of the first die, and disposed within the TIV wall;
an underfill disposed between the second die and the TIV wall and between the second die and the first redistribution structure; and
an encapsulant disposed on the first redistribution structure and laterally wrapping around the second die, the TIV wall and the TIVs, wherein a material of the underfill is different from a material of the encapsulant.

10. The package structure of claim 9, wherein the underfill is in contact with an inner side of the TIV wall and the second die, and a top surface of the underfill is substantially levelled with a top surface of the TIV wall and top surfaces of the TIVs.

11. The package structure of claim 10, wherein the encapsulant extends along an outer side of the TIV wall without contacting the second die, and a top surface of the encapsulant is substantially levelled with the top surface of the underfill.

12. The package structure of claim 9, wherein the TIV wall comprises:
a first TIV wall located beside the second die, spaced apart from and encircling the second die, and
a second TIV wall located beside the first TIV wall, spaced apart from and encircling the first TIV wall.

13. The package structure of claim 12, wherein the underfill comprises:
a first portion, disposed between the second die and the first TIV wall; and
a second portion, disposed between the first TIV wall and the second TIV wall,
wherein a top surface of the first portion of the underfill is higher than a top surface of the second portion of the underfill.

14. The package structure of claim 9, further comprising:
a third die disposed on the first redistribution structure;
another TIV wall, disposed on the first redistribution structure, beside the TIV wall and encircling the third die; and
a second redistribution structure disposed on the encapsulant and the TIV wall, the another TIV wall and the TIVs laterally wrapped by the encapsulant.

15. The package structure of claim 9, wherein the TIV wall comprises column portions and wall portions connecting the column portions, and a first width of the column portions is different from a second width of the wall portions from a top view.

16. A method of forming a package structure, comprising:
providing a first die;
forming a redistribution structure on an active surface of the first die;
forming a through insulator via (TIV) wall on the redistribution structure, wherein the TIV wall is electrically floating;
forming an array of TIVs on the redistribution structure and beside and surrounding the TIV wall, and electrically connected to the first die,
placing a second die on the redistribution structure, over the active surface of the first die and within the TIV wall from a top view, wherein the second die is electrically connected to the first die through the redistribution structure, and the TIV wall is beside the second die, spaced apart from and encircles the second die;
applying an underfill to a first gap between the second die and the TIV wall and between the second die and the redistribution structure;
laterally wrapping the second die, the TIV wall and each of the array of the TIVs by an encapsulant material on the redistribution structure; and
performing a planarization process on the second die, the TIV wall, each of the array of the TIVs and the encapsulant material to form an encapsulant laterally wrapping around the second die, the TIV wall and each of the array of the TIVs.

17. The method of claim 16, wherein forming the TIV wall further
comprising:
forming a first TIV wall located beside the second die, spaced apart from and encircling the second die, and
forming a second TIV wall located beside the first TIV wall, spaced apart from and encircling the first TIV wall.

18. The method of claim 17, wherein applying the underfill further
comprising:
applying a first portion of the underfill to the first gap between the second die and the first TIV wall, and
applying a second portion of the underfill to a second gap between the first TIV wall and the second TIV wall,
wherein a top surface of the first portion of the underfill is higher than a top surface of the second portion of the underfill.

19. The method of claim 16, wherein forming the encapsulant further comprising:
forming the encapsulant extending along an outer side of the TIV wall without contacting the second die, and a top surface of the encapsulant is substantially levelled with the top surface of the underfill.

20. The method of claim 16, further comprising:
forming an additional TIV wall on the redistribution structure;
placing a third die disposed on the redistribution structure over the first die, electrically connected to the first die, and beside the TIV wall and the second die, wherein the additional TIV wall is spaced apart from and beside the third die, and encircles the third die; and
applying an additional underfill to a third gap between the third die and the additional TIV wall, wherein the encapsulant laterally wraps around the additional TIV wall and the third die.
